(19) United States
(12) Patent Application Publication
(10) Pub. No.: US 2008/0106308 A1
(43) Pub. Date: May 8, 2008

(54) Power-on reset circuit

(75) Inventor: Yu-Jen Tu, Hsinchu (TW)

Correspondence Address: BACON & THOMAS, PLLC, 625 SLATERS LANE, FOURTH FLOOR, ALEXANDRIA, VA, 22314, US

(73) Assignee: AVID ELECTRONICS CORP., Hsinchu (TW)

(21) Appl. No.: 11/583,083

(22) Filed: Oct. 19, 2006

(51) Int. Cl. H03L 7/00

(52) U.S. Cl. 327/143

(57) ABSTRACT

The power-on reset circuit of the present invention includes a buffer, a delay circuit connected to the buffer and a constant current source circuit connected to the delay circuit. The delay circuit is made up by two capacitors, two resistors, an NMOS transistor and a PMOS transistor. The two capacitors are respectively made up by an NMOS transistor and a PMOS transistor. A current of the constant current source circuit changes along with a voltage variation of a DC power supply to respectively provide two constant voltage reference sources to the corresponding gates of the NMOS transistor and the PMOS transistor of the delay circuit. The NMOS transistor and the PMOS transistor of the constant current source circuit and the NMOS transistor and the PMOS transistor of the delay circuit form a mirroring circuit.

### BACKGROUND OF THE INVENTION

1. Field of the Invention

The invention relates in general to a power-on reset circuit, and more particularly to a power-on reset circuit that can ensure reset signal duration will not be influenced by unstable supply voltage.

2. Description of the Related Art

With reference to FIG. 5, a conventional simplified power-on reset circuit includes a buffer 70 and a delay circuit 80. The buffer 70 is consisted of a first inverter 71 and a second inverter 72 that is connected to the first inverter in series. One of the inverters 71 and 72 is a Schmitt-trigger inverter. The delay circuit 80 has two capacitors C1 and C2 and two resistors R1 and R2. The first capacitor C1 is connected to the first resistor R1 in series and the second capacitor C2 is connected to the second resistor R2 in series. A series connection node of the first capacitor C1 and the first resistor R1 is coupled to the second resistor R2. A series connection node of the second capacitor C2 and the second resistor R2 is coupled to an input terminal of the first inverter 71 of the buffer 70. The two resistors R1 and R2 can be implemented by PMOS and NMOS equivalent resistance.

The aforesaid power-on reset circuit is mainly used to connect to a reset pin of an integrated circuit to generate and provide the integrated circuit a reset signal of specific time duration. In detail, an output terminal of the second inverter 72 of the buffer 70 is coupled to the reset pin of the integrated circuit. When a direct voltage supply supplies power VDD to the power-on reset circuit, the capacitors C1, C2 start to be charged and discharged through the resistors R1 and R2, so that the output terminal of the second inverter 72 generates and outputs the reset signal of specific time duration. Hence, after the power VDD is supplied to the power-on reset circuit, the integrated circuit connected to the power-on reset circuit is reset to start an initial status.

A desired RC constant of the delay circuit 80 has to be much longer than the rising time for the direct voltage supply VDD, so as to make the reset signal hold sufficient time and make the integrated circuit complete a reset action. In addition, for some specific applications, the power-on reset circuit has to be limited to being in a small volume. Therefore, the capacitors C1 and C2 of the delay circuit 80 can be implemented by equivalent capacitors of a PMOS transistor and a NMOS transistor respectively made by a MOS semiconductor manufacturing process. On the other hand, the resistors R1 and R2 are respectively are implemented by a long length NMOS transistor and a long length PMOS transistor. Since the capacitors and the resistors are implemented by the MOS transistors, the power-on reset circuit can be made in the small volume by MOS semiconductor manufacturing process. In this way, not only the feature requirements can be fulfilled but also a space can be restrained that the volume will not become large.

However, resistance values of the resistors that are made up by long length MOS transistors are usually related to the supply voltage. A feature of the resistors is similar to a variable resistor. In this way, when a variation range of the supply voltage becomes large, such as 5.5 volts to 1.8 volts, the RC constant of the delay circuit 80 also changes at the same time. Hence a charge rate also changes, so that the reset signal duration also suddenly changes under different supply voltage. With reference to FIG. 6, a correlation of the supply voltage and the reset signal duration is shown in the diagram. When the supply voltage is 5.5 volts, the capacitors get charged very quickly due to the high voltage. Hence the reset signal duration is hardly to keep for a long time. On the contrary, when the supply voltage is 1.8 volts, the capacitors take a long time to be discharged due to the low voltage. Hence the reset signal duration can be extended. However, the variation range of the supply voltage is from 5.5 volts to 1.8 volts, and the reset signal duration changes up to eight times. In such a circumstance, it is likely to cause an incomplete reset action of the connected integrated circuit or the integrated circuit may spend too much time on the reset action.

### SUMMARY OF THE INVENTION

The main objective of the present invention is to provide a reset signal of a stable time duration that prevents the duration of the reset signal from influence of a unstable supply voltage, manufacturing process or temperature.

To achieve the main objective, the power-on reset circuit of the present invention includes at least one buffer, a delay circuit and a constant current source circuit.

The delay circuit is made up by two capacitors, two resistors, an NMOS transistor and a PMOS transistor. The two capacitors are respectively made up by an NMOS transistor and a PMOS transistor. A current of the constant current source circuit changes along with a voltage variation of a DC power supply to respectively provide two constant voltage reference sources to the corresponding gates of the NMOS transistor and the PMOS transistor of the delay circuit. The NMOS transistor and the PMOS transistor of the constant current source circuit and the NMOS transistor and the PMOS transistor of the delay circuit form a mirroring circuit.

Other objectives, advantages and novel features of the invention will become more apparent from the following detailed description when taken in conjunction with the accompanying drawings.

### BRIEF DESCRIPTION OF THE DRAWINGS

FIG. 1 is a circuit diagram of a power-on reset circuit in accordance with the present invention;

FIG. 2 is a characteristic curve diagram of reset signal duration in different supply voltage;

FIG. 3 is a characteristic curve diagram of reset signal duration under different temperature;

FIG. 4 is a characteristic curve diagram of reset signal duration under different process;

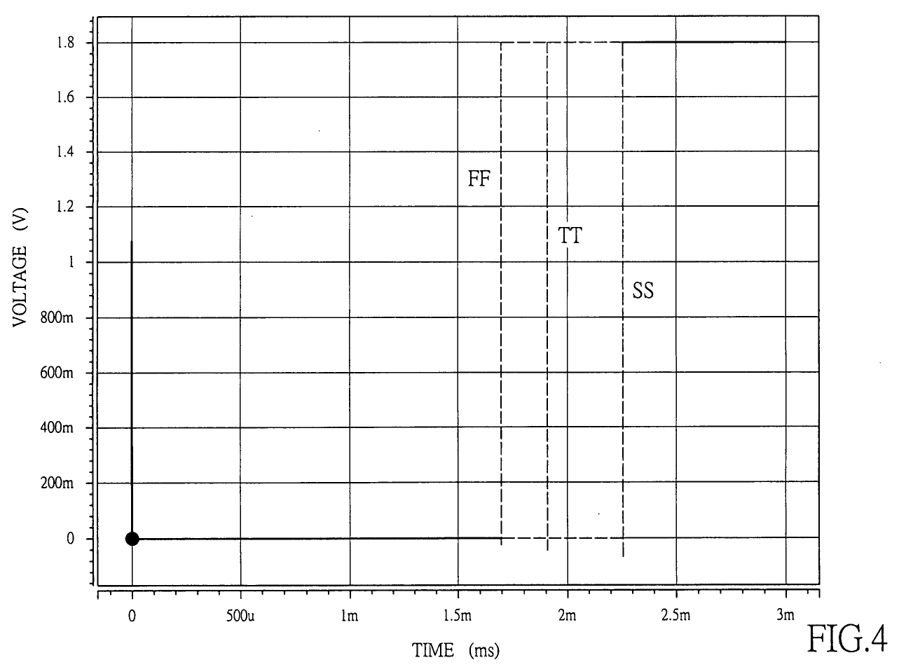

FIG. 5 is a circuit diagram of a conventional power-on reset circuit in accordance with the prior art; and

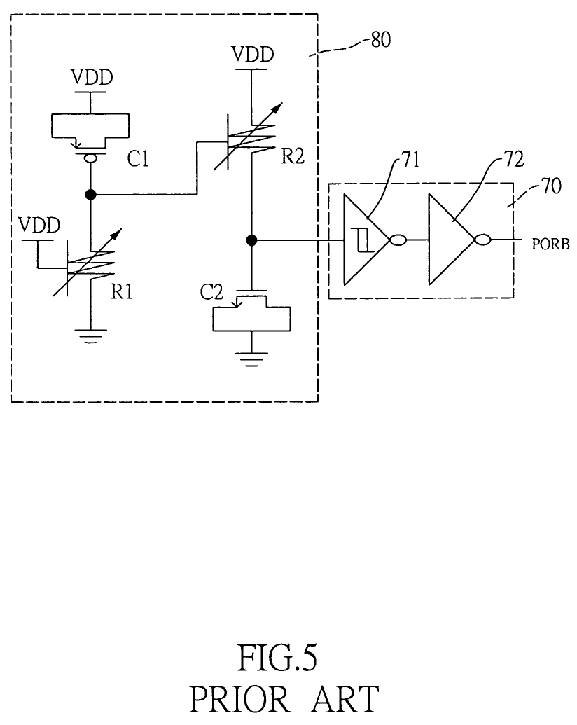

FIG. 6 is a characteristic curve diagram of a reset signal duration of the conventional power-on reset circuit in different supply voltage.

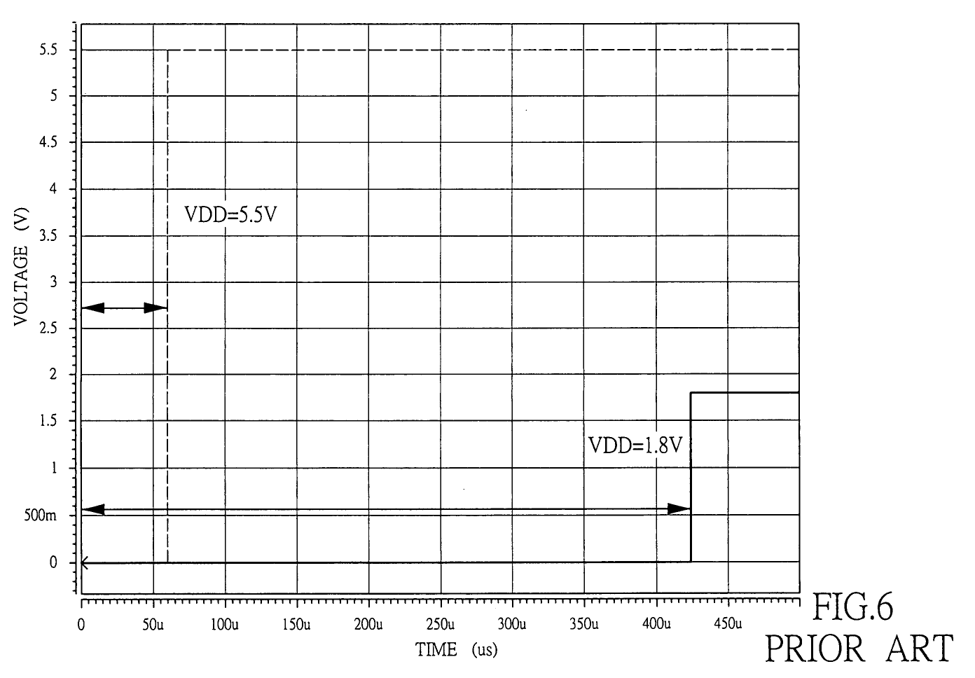

### DETAILED DESCRIPTION OF THE INVENTION

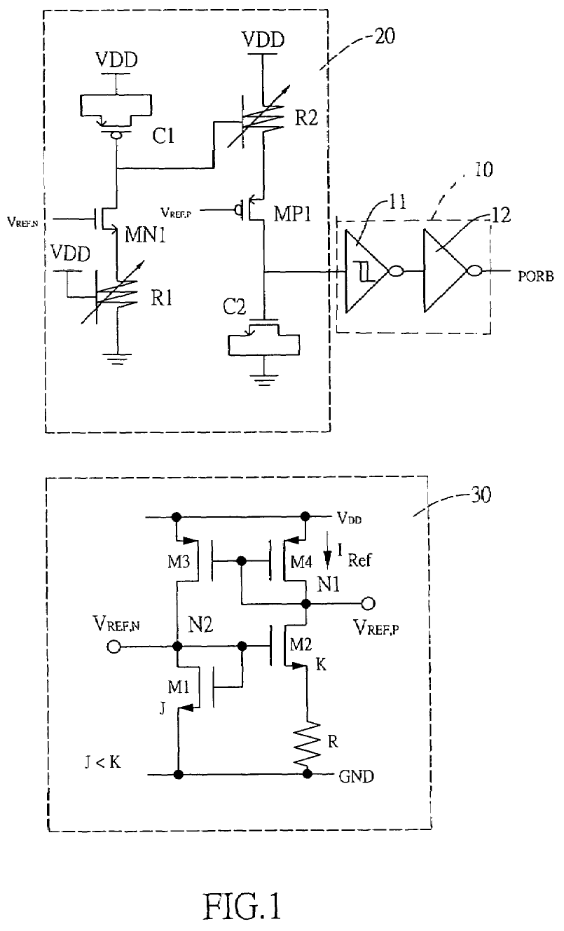

With reference to FIG. 1, a preferred embodiment of the present invention includes at least one buffer 10, a delay circuit 20 and a constant current source circuit 30. The buffer 10 has a first inverter 11 and a second inverter 12 connected to the first inverter 11 in series. In this preferred embodiment, the first inverter 11 is a Schmitt-trigger inverter, so the buffer is a Schmitt-trigger buffer.

The delay circuit 20 is connected between an input terminal of the first inverter 11 and DC voltage supply VDD. The delay circuit 20 is made up by two capacitors C1, C2, two resistors R1, R2, an NMOS transistor MN1 and a PMOS transistor MP1. In this preferred embodiment, the two capacitors C1 and C2 are respectively made up by an equivalent NMOS transistor and a PMOS transistor. The resistors R1 and R2 are made up by a long length NMOS transistor and a long length PMOS transistor, so as to effectively save a space A terminal the capacitor C1 and a terminal the resistor R1 are respectively coupled to a drain and a source of the NMOS transistor MN1, and a terminal of the capacitor C2 and a terminal of the resistor R2 are respectively coupled to a drain and a source of the PMOS transistor MP1. A connection node of the first capacitor and the drain of the NOMS transistor MN1 is coupled to the second resistor R2. A connection node of the capacitor C2 and the drain of the PMOS transistor MP1 is further coupled to the input terminal of the first inverter 11.

The constant current source circuit 30 has a first PMOS transistor M3, a second PMOS transistor M4, a first NMOS transistor M1 and a second NMOS transistor M2. Two gates of the first and second PMOS transistor M3 and M4 are connected together. A connection node of the first and the second PMOS transistors is coupled to a drain of the second PMOS transistor M4 to form a first node N1. On the other hand, two gates of the first NMOS transistor and a second NMOS transistor are coupled to each other. A connection node of the first and the second NMOS transistors M1 and M2 is coupled to a drain of the first NMOS transistor M1 to form a second node N2. The first node N1 and the second node N2 are respectively coupled to the gates of the NMOS transistor MN1 and the PMOS transistor MP1 of the delay circuit 20, so as to respectively provide a constant voltage reference source VREF,N and a constant voltage reference source VREF,P to the gates of the NMOS transistor MN1 and the PMOS transistor MP1 of the delay circuit 20. Moreover, the NMOS transistors M1 and M2 and the PMOS transistors M3 and M4 of the constant current source circuit 30 and the NMOS transistor MN1 and the PMOS transistor MP1 of the delay circuit 20 form a mirroring structure of a current mirror.

In the delay circuit 20, the long length NMOS transistor MN1 and the long length PMOS transistor MP1, which form the resistors R1 and R2 of the delay circuit 20, and the NMOS transistor MN1 and the PMOS transistor MP1 form a source degeneration circuit, so as to make charged currents for capacitors C1 and C2 close to a linear. The constant voltage reference source VREF,N and VREF,P provided by the constant current source circuit 30 make a variation rate of the charged current and the voltage supply exist a delicate relation, so as to counteract the influence of the aforesaid voltage changes to make the reset duration approximately keep a constant. To be concrete, an operation principle of the delay circuit 20 in coordination with the constant current source circuit 30 is no longer an RC charge and discharge equation but as the following equation:

$$\frac{I}{C} = \frac{d VDD}{d t}$$

In a general condition that when the capacitor is fixed, assume that Δt is a constant, then the current I∝dVDD. That is the current I and the variation rate of the supply voltage VDD must be of direct proportion to achieve the above equation.

Hence the aforesaid circuit is related to two variables of the supply voltage:

First, the long length NMOS transistor and the long length PMOS transistor that make up the resistors R1 and R2 still would change the resistance values, which works as the feature of the variable resistor.

Second, the current I can change along with the supply voltage VDD. In this point, the present invention uses a constant current source circuit to provide a relation that the output current increases along with the rising supply voltage which will be described later on. In this way, the current and the variation rate of the voltage can be of direct proportion to achieve the objective of the constant reset duration.

The constant current source circuit 30 is made up by the MOS transistors to form a feedback circuit, which is so called supply independent current mirror of the circuit. Hence the current and the voltage can keep relatively stable in the circuit and does not have a dramatic change along with the change of the power. However, the output resistance value Ro of the MOS transistors can not be infinite in reality, which means the loop gain also can not be infinite. When the supply voltage has a big change, the output current value of the constant current source circuit also shows obvious rise and fall. Therefore the present invention makes use of the aforesaid property to provide the constant voltage reference sources that slightly increase along with the rising supply voltage, so as to fulfill the aforesaid circuit demand.

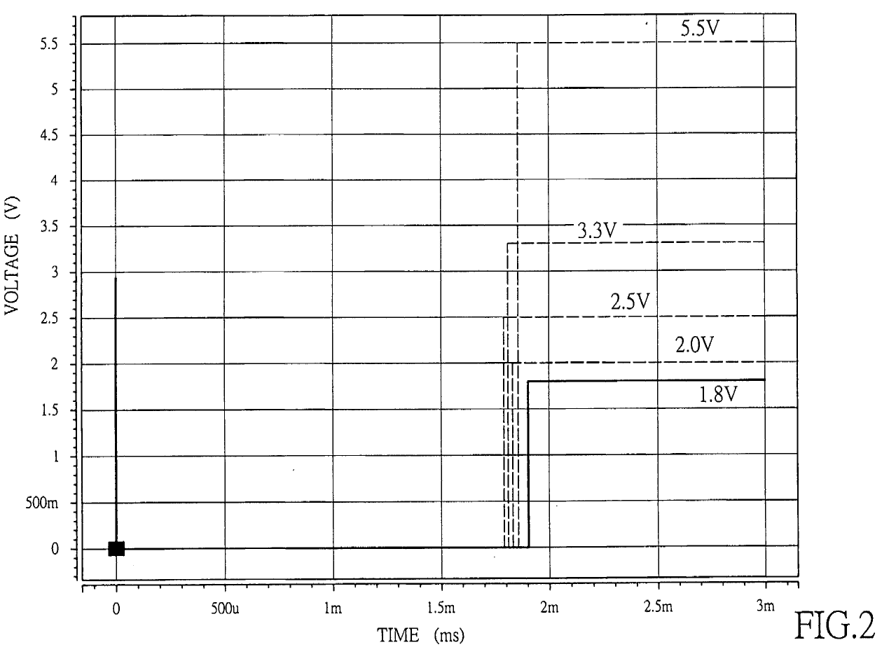

Based on forgoing description, the present invention uses the aforesaid circuit to make the charge current of the delay circuit 20 close to a linear and also make the current in proportion to the supply voltage. In this way, the relation of the variation rate of the charge current and the supply voltage is minimized, so as to make the output reset signal become stable. With reference to FIG. 2, a characteristic curve diagram of reset signal duration in different supply voltage shows that assume the supply voltage rises in three mini seconds. If the variation range of the supply voltage is from 5.5 volts to 1.8 volts and a rising time of the supply voltage is 1 ns, each reset signal duration in different supply voltage is nearly 2 mini seconds. Hence FIG. 2 indicates that when the supply voltage has a big change, the reset signal duration does not show obvious change along with the change of the supply voltage.

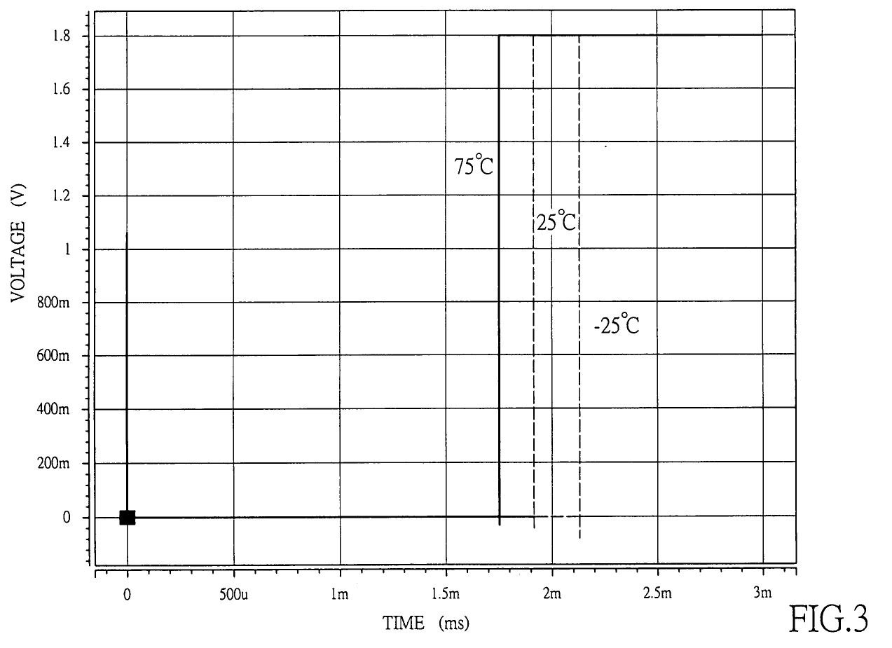

Moreover, FIG. 3 shows a characteristic curve diagram of reset signal duration under different temperature in the present invention. When the temperature is of 75° C., 25° C. and −25° C. respectively, the reset signal duration is still stable. Further, a feature curve diagram of reset signal duration under different process of FF, TT, and SS shows that the reset signal duration is still stable.

To sum up, the power-on reset circuit of the present invention can minimize the charge current variation of the reset circuit to the changes of the supply voltage, and especially when the supply voltage has a big change, the output reset signal duration still can keep stable without influenced by the voltage variation, different processes and different environmental temperatures. In this way, the reset action can be complete. Therefore, the power-on reset circuit of the present invention indeed includes features of good utility and unobviousness to meet the requirements of a patent.

Even though numerous characteristics and advantages of the present invention have been set forth in the foregoing description together with details of the structure and function of the invention, the disclosure is illustrative only. Changes may be made in detail especially in matters of shape, size, and arrangement of parts within the principles of the invention to the full extent indicated by the broad general meaning of the terms in which the appended claims are expressed.

What is claimed is:

1. A power-on reset circuit comprising:
a buffer;
a delay circuit connected between an input terminal of the buffer and a DC voltage supply and having two capacitors, two resistors, an NMOS transistor and a PMOS transistor; wherein the two capacitors are respectively made up by an NMOS transistor and a PMOS transistor, wherein
a terminal of one capacitor and a terminal of one resistor are respectively coupled to a drain and a source of the NMOS transistor, and
a terminal of a terminal of the other one capacitor and a terminal of the other one resistor are respectively coupled to a drain and a source of the PMOS transistor;
a constant current source circuit connected to gates of the NMOS transistor and the PMOS transistor, wherein a current of the constant current source circuit changes along with a voltage variation and further respectively provides two constant voltage reference sources to the corresponding gate.

2. The power-on reset circuit as claimed in claim 1, wherein the constant current source circuit comprises a first PMOS transistor and a second PMOS transistor coupled to each other by a gate, wherein a connection node of the first and the second PMOS transistors is coupled to a drain of the second PMOS transistor to form a first node, wherein a first NMOS transistor and a second NMOS transistor are coupled to each other by a gate, wherein a connection node of the first and the second NMOS transistors is coupled to a drain of the first NMOS transistor to form a second node, wherein the first node and the second node are respectively coupled to the gates of the NMOS transistor and the PMOS transistor.

3. The power-on reset circuit as claimed in claim 1, wherein the buffer comprises a Schmitt-trigger inverter and an inverter connected to the schmitt-trigger inverter in series.

4. The power-on reset circuit as claimed in claim 1, wherein the resistors are made up by a long length NMOS transistor and a long length PMOS transistor.

5. The power-on reset circuit as claimed in claim 1, wherein the NMOS transistor and the PMOS transistor of the constant current source circuit and the first and second NMOS transistors and the first and second PMOS transistors of the delay circuit form a mirroring circuit.
